(19) United States
(12) Patent Application Publication
(10) Pub. No.: US 2016/0089622 A1
(43) Pub. Date: Mar. 31, 2016

(54) METHOD OF PURIFYING LIQUID CHEMICAL FOR SEMICONDUCTOR PHOTOLITHOGRAPHY, PURIFICATION DEVICE OF LIQUID CHEMICAL FOR SEMICONDUCTOR PHOTOLITHOGRAPHY, AND LIQUID CHEMICAL FOR SEMICONDUCTOR PHOTOLITHOGRAPHY

(71) Applicant: TOKYO OHKA KOGYO CO., LTD., Kawasaki-shi (JP)

(72) Inventors: Hayato Takashima, Kawasaki-shi (JP); Takao Nakajima, Kawasaki-shi (JP)

(21) Appl. No.: 14/863,611

(22) Filed: Sep. 24, 2015

(30) Foreign Application Priority Data
Sep. 29, 2014 (JP) 2014-198015

(51) Int. Cl. B01D 35/02; C09K 3/00; G03F 7/16

(52) U.S. Cl. CPC B01D 35/02; G03F 7/16; C09K 3/00

(57) ABSTRACT

A method of purifying a liquid chemical for semiconductor photolithography including filtering a liquid chemical using a filter unit, and setting a temperature of the liquid chemical passing through at least the filter unit to be lower than room temperature. The temperature which is lower than room temperature is preferably 25° C.

### BACKGROUND OF THE INVENTION

1. Field of the Invention

The present invention relates to a method of purifying a liquid chemical for semiconductor photolithography, a purification device of a liquid chemical for semiconductor photolithography, and a liquid chemical for a semiconductor photolithography.

Priority is claimed on Japanese Patent Application No. 2014-198015, filed on Sep. 29, 2014, the contents of which are incorporated herein by reference.

2. Description of Related Art

In a lithographic technique, for example, a process of forming a resist pattern having a predetermined shape on a resist film is performed by forming the resist film formed of a resist material on a substrate, performing selective exposure using radiation such as light or electron beams through a mask on which a predetermined pattern is formed with respect to the resist film, and carrying out a developing treatment. In the lithographic technique, various liquid chemicals such as a developer, a resist solvent, and a pre-wet solvent are used. A method of applying a filter has been conventionally used as a method of removing particles or impurities mixed with these liquid chemicals (for example, Japanese Unexamined Patent Application, First Publication No. 2005-243728).

Meanwhile, when an ultrafine pattern is produced, since pattern performance is affected by fine particles existing in a liquid chemical, a liquid chemical which has low concentration and does not contain even minimal impurities is desired.

In recent years, when a liquid chemical is brought into contact with a supply container or a supply member during storage or transportation of the liquid chemical, it has been found that elution of a resin or a metal constituting a supply container or a supply member contributes to contamination of the liquid chemical in the contact portion. Japanese Unexamined Patent Application, First Publication No. 2014-112176 describes that a predetermined material is used for an inner wall of a supply container or a supply member in order to reduce elution of impurities caused by a liquid chemical being brought into contact with the supply container or the supply member.

### SUMMARY OF THE INVENTION

A liquid chemical for semiconductor photolithography has been required to have higher quality and there is room for improvement in a method of purifying the liquid chemical for semiconductor photolithography.

The present invention has been made in consideration of the above-described problems, and an object thereof is to provide a method of purifying a liquid chemical for semiconductor photolithography which is capable of reducing elution from a member.

According to a first aspect of the present invention, there is provided a method of purifying a liquid chemical for semiconductor photolithography, including filtering a liquid chemical using a filter unit, in which a temperature of the liquid chemical passing through at least the filter unit is set to be lower than room temperature.

According to a second aspect of the present invention, there is provided a purification device of a liquid chemical for semiconductor photolithography, including: a liquid chemical storage tank; a filter unit which is connected to the liquid chemical storage tank through an introduction pipe; a pump which sends a liquid chemical in the liquid chemical storage tank out to the filter unit; a supply pipe which supplies the liquid chemical filtered by the filter unit; and a cooling device which sets the temperature of the liquid chemical passing through at least the filter unit to be lower than room temperature.

According to a third aspect of the present invention, there is provided a liquid chemical for semiconductor photolithography, in which the density of particles which are applied to a substrate and have a diameter of 30 nm or greater after a baking treatment is performed is less than 0.15 per square centimeter.

According to the present invention, it is possible to provide a method of purifying a liquid chemical for semiconductor photolithography which is capable of reducing elution from a member.

### BRIEF DESCRIPTION OF THE DRAWINGS

FIG. 1 is a view illustrating a schematic configuration of a purification device of a liquid chemical for semiconductor photolithography according to an embodiment of the present invention.

### DETAILED DESCRIPTION OF THE INVENTION

### Method of Purifying Liquid Chemical for Semiconductor Photolithography

A first embodiment of the present invention relates to a method of purifying a liquid chemical for semiconductor photolithography which includes a process of filtering the liquid chemical using a filter unit and in which the temperature of the liquid chemical passing through at least the filter unit is set to be lower than room temperature.

According to the purification method of the present invention, it is possible to remove impurities in the liquid chemical using the filter unit and possible to prevent the generation of particles due to elution from members caused by the liquid chemical being brought into contact with various members during a filtering process and other purification processes.

In the present specification, the “particles” indicate various impurities having an influence on a formation pattern in the field of photolithography and indicate mainly resin impurities or metal impurities.

According to the present invention, in the process of filtering the liquid chemical using the filter unit, the temperature of the liquid chemical passing through at least the filter unit is set to be lower than room temperature.

The filter unit includes a filter; an accommodation unit that accommodates the filter; an inlet portion of the liquid chemical; and an ejection unit of the liquid chemical and an accommodation unit which can be blocked is preferable for the accommodation unit.

The liquid chemical flowing in the filter unit passes through the filter and is discharged from the ejection unit.

A filtration filter having a hole diameter of several nanometers to several tens of nanometers can be employed as the filter being used in the process.

The material of the filter being used may be suitably selected according to the liquid chemical to be produced, and, specifically, a filtration filter made of polyethylene, polypropylene, polytetrafluoroethylene, nylon, or polyamide can be employed. Among these, in the present invention, it is preferable to use a filtration filter made of polyethylene, polypropylene, polytetrafluoroethylene, or nylon and particularly preferable to use a filtration filter made of polyethylene or polytetrafluoroethylene.

The structure of the filter unit is not particularly limited and the filter unit may be used as a single filter unit using a single filtration filter or may be used as a multi-stage filter unit obtained by combining plural kinds of filtration filters. In this case, the material, the shape, and the hole diameter of the filter may vary in each of the filtration processes.

The filtration process using the filter unit is performed for the purpose of removing fine particles existing in the liquid chemical while the liquid chemical is used. However, by the liquid chemical being brought into contact with the filter in the filtration process, a low molecular compound or the like (a low molecular compound or the like remaining in a synthesis process of a resin) contained in a resin constituting a filter member in the contact portion is eluted in the liquid chemical in some cases.

In the filtration process, there is a problem in that particles generated due to elution from a member are mixed with the liquid chemical.

The present invention solves the above-described problem by setting the temperature of the liquid chemical passing through at least the filter unit to be lower than room temperature.

In the present invention, elution of a resin from a filter member can be reduced by setting the temperature of the liquid chemical passing through at least the filter unit to be lower than room temperature. The setting of the temperature is particularly useful to reduce particles generated due to a resin eluted from the filter member.

In addition, in order to suppress generation of particles, other processes or whole processes in the purification process of the liquid chemical may be carried out at a temperature which is lower than room temperature. In the purification process of the liquid chemical, the liquid chemical is brought into contact with various members such as a supply pipe, an accommodation unit, and a connection member. Since elution from members may occur in any of these members, particles generated due to the elution from members can be reduced by performing other processes or whole processes in the purification process of the liquid chemical at a temperature which is lower than room temperature.

In the present invention, the temperature of the liquid chemical passing through at least the filter unit may be set to be lower than room temperature or the temperature of whole processes of passing the liquid chemical may be set to be lower than room temperature.

In the present invention, the method of setting the temperature of the liquid chemical passing through the filter unit to be lower than room temperature may be performed such that the temperature of the liquid chemical in an inlet which allows the liquid chemical to flow in the filter unit and the temperature of the liquid chemical in an outlet are set to be lower than room temperature. Specifically, a method of disposing the filter unit, the inlet allowing the liquid chemical to flow in the filter unit, and the outlet in a thermostatic bath and setting the temperature thereof to be lower than room temperature can be employed.

In a case where the temperature of the whole purification process of the liquid chemical is set to be lower than room temperature, a method of disposing the filter unit and the like described above in the thermostatic bath and performing the purification process in a chamber whose temperature is set to be lower than room temperature can be employed.

Preferably, the purification method of the present invention is performed using a purification device described below and the liquid chemical may be circulated several times in the purification device described below so as to pass through the filter unit several times.

In the present invention, the “temperature which is lower than room temperature” is preferably lower than 25° C. and more preferably lower than 22° C. Further, the temperature thereof is preferably 0° C. or higher, more preferably 5° C. or higher, and particularly preferably 10° C. or higher.

These upper limits and lower limits can be arbitrarily combined with each other.

The surface area of the filter, the filtration pressure, and the flow rate at the time when the liquid chemical passes through the filter can be suitably adjusted according to the amount or the kind of liquid chemical to be used, but are not particularly limited.

In the present invention, the filtration process is carried out by filtering the liquid chemical at a filtration pressure preferably in the range of 0.08 MPa to 0.15 MPa and more preferably in the range of 0.1 MPa to 0.14 MPa. Moreover, in the present invention, the liquid chemical may be subjected to pressure filtration using inert gas during the filtration process.

For example, nitrogen can be used as the inert gas.

Liquid Chemical

The liquid chemical which can be used in the present invention will be described.

The purification method of the present invention can be applied to various liquid chemicals used for the semiconductor photolithography and used as a pre-wet solvent, a resist solvent, and a developer.

As the liquid chemical, a polar solvent such as a ketone-based solvent, an ester-based solvent, an alcohol-based solvent, an amide-based solvent, or an ether-based solvent and a hydrocarbon-based solvent can be used.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetyl carbinol, acetophenone, methyl naphthyl ketone, isophorone, and propylene carbonate. Among these, cyclohexanone is particularly useful for the purification method of the present invention.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutylacetate, 3-methyl-3-methoxybutylacetate, methyl formate, ethyl formate, butyl formate, propyl formate, ethyl lactate, butyl lactate, and propyl lactate.

Examples of the alcohol-based solvent include alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, or n-decanol; a glycol-based solvent such as ethylene glycol, diethylene glycol, or triethylene glycol; and a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxy methyl butanol.

Examples of the ether-based solvent include dioxane and tetrahydrofuran in addition to the glycol ether-based solvents described above.

Examples of the amide-based solvent include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include an aromatic hydrocarbon-based solvent such as toluene or xylene; and an aliphatic hydrocarbon-based solvent such as pentane, hexane, octane, or decane.

A plurality of the above-described solvents may be used in combination or the solvents may be used by being mixed with other solvents.

Since the purification method of the present invention is performed at a temperature which is lower than room temperature and can reduce generation of particles caused by elution from a member, the purification method thereof is particularly useful in a case where a purification device using a member from which a liquid chemical to be purified is highly likely to be eluted is used.

As the liquid chemical which is highly likely to be eluted from a member when the liquid chemical is brought into contact with the member, a liquid chemical in which a value of the interaction radius (R0) to be calculated by a Hansen solubility parameter of a member in contact with the liquid chemical and a value of the radius (Ra) of a sphere in a Hansen space to be calculated by the Hansen solubility parameter of the liquid chemical are in a relationship of “Ra/R0≦1” is exemplified, and the purification method of the present invention can be suitably used for these liquid chemicals.

The liquid chemical which can be suitably used for the present invention can be selected from liquid chemicals satisfying predetermined parameters based on a solubility parameter and aggregation properties explained by Charles Hansen in “Hansen Solubility Parameter: A User's Handbook” written by Charles M. Hansen and “The CRC Handbook and Solubility Parameters and Cohesion Parameters” (1999) edited by CRC Press (2007) and Allan F. M. Barton (1999). The predetermined parameters can be calculated as described below.

The liquid chemical used in purification and constituent materials of members are each regulated using three points in a three-dimensional space.

These three points are acquired by the Hansen solubility parameter (HSP) which can be defined as follows.

The Hansen solubility parameter is theoretically calculated as a numerical constant and used as a useful tool to predict the ability of a solvent material to allow a specific solute to be dissolved therein. When the solubility parameter of the liquid chemical is in the range of the solubility parameter of a constituent material of a member, that is, a material to be dissolved, there is a possibility that solubilization of the constituent material of the member in the liquid chemical occurs.

There are three Hansen solubility parameters that are experimentally and theoretically derived, that is, a dispersion force component (δD), a polar or dipolar interaction component (δP), and a hydrogen bond component (δH). The three parameters (that is, the dispersion, the polar, and the hydrogen bond) represent characteristics of dissolving power, that is, solvent ability of the liquid chemical. The three parameters can be used as a measure of overall strength and selectivity of the liquid chemical by being combined. As a unit of the solubility parameter, MPa^{0.5} or (J/cc)^{0.5} is provided.

These three parameters (that is, the dispersion, the polar, and the hydrogen bond) are plotted as coordinates related to points in a three-dimensional space which is known as a Hansen space.

When two kinds of molecules (a liquid chemical and a constituent material of a member) become close in the three-dimensional space, this indicates that the possibility of the constituent material thereof to be dissolved in the liquid chemical becomes higher. That is, a value referred to as the interaction radius (R0) is provided for a material to be dissolved because the value determines whether the parameter of two molecules (a liquid chemical and a constituent material of a member) is in the range. The value determines the radius of a sphere in the Hansen space and the center thereof indicates three Hansen parameters. When the distance (Ra) between Hansen parameters in the Hansen space is calculated, the following expression is used.

(Ra)²=4(δ_{d2}−δ_{d1})²+(δₚ₂−δₚ₁)²+(δₕ₂−δₕ₁)²

The Hansen solubility parameter can be calculated by “Molecular Modeling Pro” software, version 5.1.9 (ChemSW, Fairfield Calif., www.chemsw.com) or Hansen Solubility from Dynacomp Software. The solubility parameters of the liquid chemical which can be suitably used in the present invention are listed in Table 1 below. Further, the purification method of the present invention is particularly useful for the liquid chemical satisfying the relationship of “Ra/R0≦1” between R0 and Ra described above. The values of Ra/R0 are also listed in Table 1 below.

TABLE 1

| | Dispersion | | Hydrogen | Ra/R0 (with |
|---|---|---|---|---|
| | (δD) | Polar (δP) | bond (δH) | polyethylene) |
| PGMEA | 16 | 5.6 | 9.8 | 0.92 |
| 1-butanol | 15.8 | 3.7 | 6.3 | 0.54 |
| Ethyl acetate | 15.8 | 5.3 | 7.2 | 0.51 |
| Isoamyl acetate | 15.3 | 3.1 | 7 | 0.52 |
| Diethyl carbonate | 16.6 | 3.1 | 6.1 | 0.55 |
| Methyl ethyl ketone | 16 | 9 | 5.1 | 0.5 |
| Acetone | 15.5 | 10.4 | 7 | 0.84 |
| Methyl isobutyl | 15.3 | 6.1 | 4.1 | 0.23 |
| ketone | | | | |
| Cyclohexanone | 17.8 | 6.3 | 5.1 | 0.76 |
| Diethyl ketone | 15.8 | 7.6 | 4.7 | 0.43 |
| Methyl isobutyl | 16 | 5.7 | 4.1 | 0.32 |
| ketone | | | | |
| Di(isobutyl)ketone | 16 | 3.7 | 4.1 | 0.37 |
| Methylene chloride | 18.2 | 6.3 | 6.1 | 0.9 |
| 1,1-dichloroethylene | 17 | 6.8 | 4.5 | 0.58 |
| Chloroform | 17.8 | 3.1 | 5.7 | 0.83 |
| Tetrahydrofuran | 16.8 | 5.6 | 8 | 0.8 |
| Hexanone | 14.9 | 0 | 0 | 0.72 |
| Heptane | 15.3 | 0 | 0 | 0.72 |
| Octane | 15.5 | 0 | 0 | 0.72 |
| Toluene | 18 | 1.4 | 2 | 0.87 |

As the liquid chemical which is particularly useful for the purification method of the present invention, a liquid chemical in which the value of Ra/R0 is 0.98 or less is preferable, a liquid chemical in which the value of Ra/R0 is 0.95 or less is more preferable, and a liquid chemical in which the value of Ra/R0 is 0.9 or less is particularly preferable.

Further, a liquid chemical in which the value of Ra/R0 is 0.5 or greater is preferable, a liquid chemical in which the value of Ra/R0 is 0.6 or greater is more preferable, and a liquid chemical in which the value of Ra/R0 is 0.7 or greater is particularly preferable.

These upper limits and lower limits can be arbitrarily combined with each other.

Purification Device of Liquid Chemical for Semiconductor Photolithography

A second embodiment of the present invention relates to a purification device of a liquid chemical for semiconductor photolithography, including: a liquid chemical storage tank; a filter unit which is connected to the liquid chemical storage tank through an introduction pipe; a pump which sends a liquid chemical in the liquid chemical storage tank out to the filter unit; a supply pipe which supplies the liquid chemical filtered by the filter unit; and a cooling device which sets the temperature of the liquid chemical passing through at least the filter unit to be lower than room temperature.

Hereinafter, the method of purifying a liquid chemical for semiconductor photolithography of the present invention will be described with reference to the accompanying drawings.

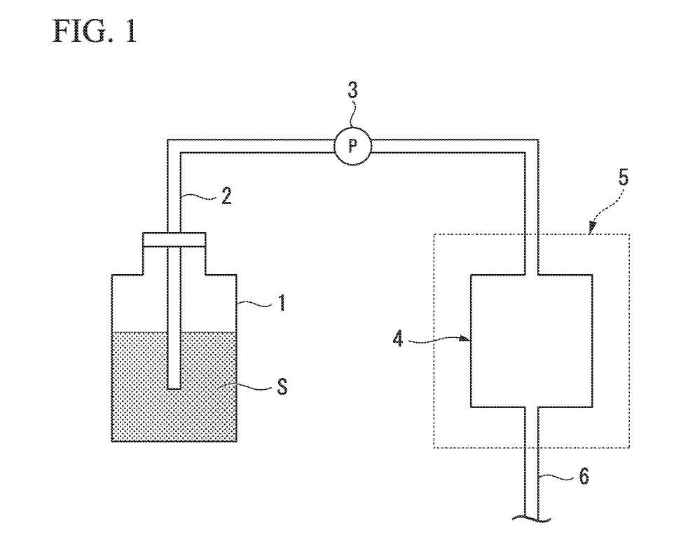

FIG. 1 is a view illustrating a schematic configuration of the purification device of a liquid chemical for semiconductor photolithography according to the embodiment of the present invention.

In FIG. 1, a liquid chemical storage tank 1 is capable of storing a liquid chemical S. In addition, the liquid chemical storage tank 1 is connected to the inlet side of a filter unit 4 through an introduction pipe 2. The introduction pipe 2 is provided with a pump 3 that sends the liquid chemical S stored in the liquid chemical storage tank 1 out to the filter unit 4. In addition, a supply pipe 6 is disposed in the outlet side of the filter unit 4.

In the present invention, a cooling device 5 that sets the temperature of the liquid chemical passing through at least the filter unit to be lower than room temperature is provided. The temperature of the liquid chemical passing through the filter unit can be adjusted to be lower than room temperature by the cooling device 5. In the present invention, it is preferable that the temperature which is lower than room temperature is set to be lower than 25° C. As the cooling device 5, for example, a thermostatic bath or the like may be disposed.

Moreover, it is preferable that the pump 3 is an inert gas introduction type pump.

Liquid Chemical for Semiconductor Photolithography

A third embodiment of the present invention relates to a liquid chemical for semiconductor photolithography, in which the density of particles which are applied to a substrate and have a diameter of 30 nm or greater after a baking treatment is performed is less than 0.15 per square centimeter. As the method of purifying the liquid chemical of the present invention, which is not particularly limited, it is preferable to employ the purification method of the first embodiment of the present invention.

The liquid chemical purified by the purification method according to the first embodiment of the present invention has an extremely small amount of ultrafine particles having a diameter of 30 nm or greater because of reduction in mixture of particles generated due to elution from a member. As the liquid chemical for semiconductor photolithography of the present invention, a pre-wet solvent, a resist solvent, or a developer is exemplified and, among these, a pre-wet solvent is preferable.

### EXAMPLES

Hereinafter, the present invention will be described in detail with reference to Examples, but the present invention is not limited to Examples described below.

### Production of Liquid Chemical for Semiconductor Photolithography

Cyclohexanone (manufactured by UBE INDUSTRIES, LTD.) was filtered under reduced pressure (under nitrogen pressure, 0.04 MPa) using an ultrahigh molecular weight polyethylene (UPE) filtration filter having a pore size of 5 nm and a liquid chemical for photolithography for evaluation was produced. Ra/R0 of cyclohexanone to polyethylene was 0.76. The production process was performed in a thermostatic bath by setting the temperature of the liquid chemical to a predetermined temperature. A production process carried out at 20° C. was set as Example 1, a production process carried out at room temperature (25° C.) was set as Comparative Example 1, and a production process carried out at 30° C. was set as Comparative Example 2.

Evaluation of Particles

Evaluation of particles in cyclohexanone of Example 1 and Comparative Examples 1 and 2 was performed. Silicon wafers (wafers 1 and 2) each having a diameter of 300 nm were coated with cyclohexanone of Example 1 and Comparative Examples 1 and 2 using a spinner (at 1500 rpm for 1 minute) and were baked on a hot plate at 80° C. for 60 seconds. Subsequently, particles on the silicon wafers were observed using a surface observation device SURFSCANSP2 (manufactured by KLA-Tencor Corporation), thereby determining the number of particles. The results thereof are listed in Table 2.

TABLE 2

| | Wafer 1 | Wafer 2 |
|---|---|---|
| Example 1 | 23 | 37 |
| Comparative Example 1 | 151 | 73 |
| Comparative Example 2 | 6765 | 6536 |

As understood from Table 2, the number of particles of Example 1, in which the filtration process was carried out at 20° C. that was lower than room temperature, was small.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### EXPLANATION OF REFERENCES

S: LIQUID CHEMICAL

1: LIQUID CHEMICAL STORAGE TANK

2: INTRODUCTION PIPE

3: PUMP

4: FILTER UNIT

5: COOLING DEVICE

6: SUPPLY PIPE

What is claimed is:

1. A method of purifying a liquid chemical for semiconductor photolithography, comprising filtering a liquid chemical using a filter unit, wherein a temperature of the liquid chemical passing through at least the filter unit is set to be lower than room temperature.

2. The method of purifying a liquid chemical for semiconductor photolithography according to claim 1, wherein the temperature which is lower than room temperature is lower than 25° C.

3. The method of purifying a liquid chemical for semiconductor photolithography according to claim 1, wherein a value of an interaction radius (R0) calculated by a Hansen solubility parameter of a member in contact with the liquid chemical and a value of a radius (Ra) of a sphere in a Hansen space calculated by the Hansen solubility parameter of the liquid chemical, satisfy a relationship of Ra/R0≦1.

4. The method of purifying a liquid chemical for semiconductor photolithography according to claim 2, wherein a value of an interaction radius (R0) calculated by a Hansen solubility parameter of a member in contact with the liquid chemical and a value of a radius (Ra) of a sphere in a Hansen space calculated by the Hansen solubility parameter of the liquid chemical satisfy a relationship of Ra/R0≦1.

5. The method of purifying a liquid chemical for semiconductor photolithography according to claim 1, wherein the liquid chemical is filtered at a filtration pressure of 0.08 MPa to 0.15 MPa.

6. The method of purifying a liquid chemical for semiconductor photolithography according to claim 2, wherein the liquid chemical is filtered at a filtration pressure of 0.08 MPa to 0.15 MPa.

7. The method of purifying a liquid chemical for semiconductor photolithography according to claim 3, wherein the liquid chemical is filtered at a filtration pressure of 0.08 MPa to 0.15 MPa.

8. The method of purifying a liquid chemical for semiconductor photolithography according to claim 4, wherein the liquid chemical is filtered at a filtration pressure of 0.08 MPa to 0.15 MPa.

9. The method of purifying a liquid chemical for semiconductor photolithography according to claim 1, wherein the liquid chemical is subjected to pressure filtration using inert gas.

10. The method of purifying a liquid chemical for semiconductor photolithography according to claim 2, wherein the liquid chemical is subjected to pressure filtration using inert gas.

11. The method of purifying a liquid chemical for semiconductor photolithography according to claim 3, wherein the liquid chemical is subjected to pressure filtration using inert gas.

12. The method of purifying a liquid chemical for semiconductor photolithography according to claim 4, wherein the liquid chemical is subjected to pressure filtration using inert gas.

13. The method of purifying a liquid chemical for semiconductor photolithography according to claim 5, wherein the liquid chemical is subjected to pressure filtration using inert gas.

14. The method of purifying a liquid chemical for semiconductor photolithography according to claim 6, wherein the liquid chemical is subjected to pressure filtration using inert gas.

15. The method of purifying a liquid chemical for semiconductor photolithography according to claim 7, wherein the liquid chemical is subjected to pressure filtration using inert gas.

16. A purification device of a liquid chemical for semiconductor photolithography, comprising:
a liquid chemical storage tank;
a filter unit which is connected to the liquid chemical storage tank through an introduction pipe;
a pump which sends a liquid chemical in the liquid chemical storage tank out to the filter unit;
a supply pipe which supplies the liquid chemical filtered by the filter unit; and
a cooling device which sets the temperature of the liquid chemical passing through at least the filter unit to be lower than room temperature.

17. The purification device of a liquid chemical for semiconductor photolithography according to claim 16, further comprising a cooling device which sets the temperature which is lower than room temperature to 25° C.

18. The purification device of a liquid chemical for semiconductor photolithography according to claim 16, wherein the pump is an inert gas introduction-type pump.

19. The purification device of a liquid chemical for semiconductor photolithography according to claim 17, wherein the pump is an inert gas introduction-type pump.

20. A liquid chemical for semiconductor photolithography, wherein the density of particles which are applied to a substrate and have a diameter of 30 nm or greater after a baking treatment is performed is less than 0.15 per square centimeter.
